(19) United States
(12) Patent Application Publication
(10) Pub. No.: US 2008/0205049 A1
(43) Pub. Date: Aug. 28, 2008

(54) Water-actuated survival lamp unit with an LED light source

(75) Inventor: John Errington Brain, Pierrefonds (CA)

Correspondence Address: KLARQUIST SPARKMAN, LLP, 121 SW SALMON STREET, SUITE 1600, PORTLAND, OR, 97204, US

(73) Assignee: RUTTER INC.

(21) Appl. No.: 12/072,088

(22) Filed: Feb. 22, 2008

Related U.S. Application Data
(60) Provisional application No. 60/891,405, filed on Feb. 23, 2007.

(51) Int. Cl. F21L 4/00; G01R 27/26

(52) U.S. Cl. 362/158; 324/679

(57) ABSTRACT

Embodiments of water activated survival lamp units for mounting to a flotation device above and in proximity to the water line are disclosed. In one exemplary embodiment, the survival lamp unit has a light source including a LED array having a plurality of semi conducting light emitting chips encased in a unitary lens structure through which the semi conducting light emitting chips output light. The exemplary survival lamp unit further includes a water responsive actuator for controlling the operation of the light source, responsive to a momentary contact with a coherent body of water for actuating the light source for an operative cycle of a time period largely exceeding a duration of the momentary contact. In some implementations, when the survival lamp unit is actuated, it emits either fixed light or flashing light in generally all directions of the upper hemisphere.

### CROSS REFERENCE TO RELATED APPLICATIONS

This application claims the benefit of U.S. provisional application 60/891,405 entitled “Water-actuated survival lamp unit with an LED light source” filed on Feb. 23, 2007, the contents of which are incorporated herein by reference.

### FIELD

This application relates to a water-activated survival lamp unit mounted to a flotation device such as a life jacket.

### BACKGROUND

Water-actuated survival lamp units are known in the art. However current technologies have numerous drawbacks, including short battery life and high manufacturing costs. Accordingly, it is an object of some embodiments of the disclosed technology to provide a water-actuated survival lamp unit that alleviates these problems.

### SUMMARY

Among the exemplary embodiments disclosed herein are embodiments of a water activated survival lamp unit for mounting to a flotation device above and in proximity to the water line. In some embodiments, the survival lamp unit has a light source including an LED array having a plurality of semi conducting light emitting chips encased in a unitary lens structure through which the semi conducting light emitting chips output light. The survival lamp unit further includes a water responsive actuator for controlling the operation of the light source, responsive to a momentary contact with a coherent body of water for actuating the light source for an operative cycle of a time period largely exceeding a duration of the momentary contact. When the survival lamp unit is actuated, it emits either fixed light or flashing light in generally all directions of the upper hemisphere with, for example, a luminous intensity of least 0.75 cd if the light source emits fixed light, or an effective luminous intensity of at least 0.75 cd if the light source emits flashing light.

In some embodiments, the survival lamp unit has a housing including at least two sections mated to one another along an area of juncture and a light source including a LED light unit mounted in the housing. A water responsive actuator is provided for controlling operation of the light source, responsive to a momentary contact with a coherent body of water for actuating the light source for an operative cycle of a time period largely exceeding a duration of the momentary contact. The water responsive actuator can include at least one electrode projecting outside the housing and an electrical pathway from the electrode to the interior of the housing, the electrical pathway passing between the mated sections through the area of juncture.

In certain embodiments, the survival lamp unit has a housing and a light source including a LED light unit mounted in the housing. The survival lamp unit has also a water responsive actuator for controlling operation of the light source, responsive to a momentary contact with a coherent body of water for actuating the light source for an operative cycle of a time period largely exceeding a duration of the momentary contact, the water responsive actuator including at least one electrode projecting outside the housing. The survival lamp unit of these embodiments also includes a tamper-proof structure associated with the electrode to prevent contact between the electrode and the skin when the survival lamp unit is hand-manipulated.

Other exemplary embodiments of the disclosed technology include methods for determining a capacity of a battery of a water activated survival lamp unit, the water activated survival lamp unit intended for mounting to a flotation device above and in proximity to the water line and comprising: a light source including a battery operated LED array having a plurality of semi conducting light emitting chips encased in a unitary lens structure through which the semi conducting light emitting chips output light, and a water responsive actuator for controlling operation of the light source, the actuator being responsive to a momentary contact with a coherent body of water for actuating the light source for an operative cycle of a time period largely exceeding a duration of the momentary contact. In certain implementations, the method includes determining an energy requirement for the survival lamp unit such that when actuated it emits either fixed light or flashing light in generally all directions of the upper hemisphere with, for example, a luminous intensity of least 0.75 cd of at least 8 hours of continuous operation if the light source emits fixed light or an effective luminous intensity of at least 0.75 cd of at least 8 hours of continuous operation if the light source emits flashing light. The method can further include determining an energy requirement to perform a test cycle of the survival lamp unit at least 5 times, wherein a test cycle includes actuating the survival lamp unit over a certain period of time, and selecting a battery that has a capacity sufficient to meet the energy requirements.

The foregoing and other objects, features, and advantages of embodiments of the disclosed technology will become more apparent from the detailed description, which proceeds with reference to the accompanying figures.

### BRIEF DESCRIPTION OF THE DRAWINGS

FIG. 1 is a perspective view of a life vest provided with a survival lamp unit according to a non-limiting exemplary embodiment of the disclosed technology.

FIG. 2 is an enlarged perspective view of the survival lamp unit shown in FIG. 1.

FIG. 3 is another view of the survival lamp unit shown in FIG. 2, illustrating in greater detail the mounting structure to a life vest.

FIG. 4 is a perspective view of another embodiment of the survival lamp unit of FIG. 2.

FIG. 5 is a perspective view of the survival lamp unit of FIG. 4, the lid thereof being removed to show the internal construction of the survival lamp unit.

FIG. 6 is a perspective view of another embodiment of the survival lamp unit of FIG. 2.

FIG. 7 is another view of the survival lamp unit shown in FIG. 6, showing the bottom portion being separated from the top portion to illustrate the assembly of the survival lamp unit.

FIG. 8 is a block diagram of an example electrical circuit for operating the survival lamp unit.

FIG. 9 is a flowchart that describes the operation of one embodiment of a survival lamp unit.

In the drawings, embodiments of the disclosed technology are illustrated by way of example. It is to be expressly understood that the description and drawings are only for purposes of illustration and as an aid to understanding, and are not intended to be a definition of the limits of the invention.

### DETAILED DESCRIPTION

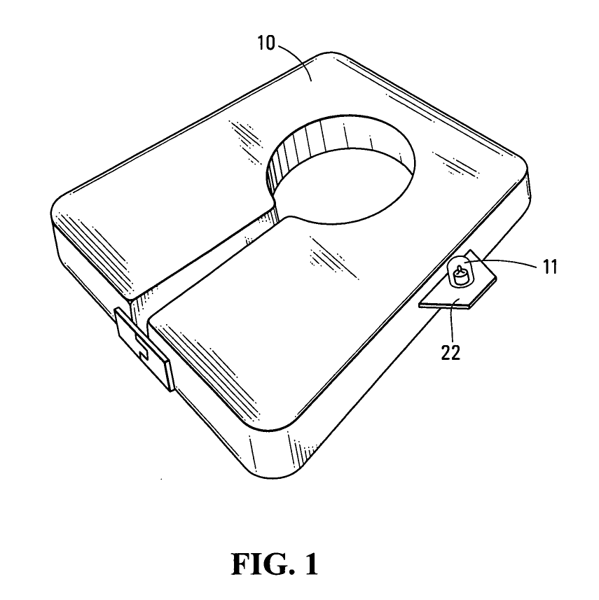

FIG. 1 illustrates a personal flotation device, such as a life vest 10 that is provided with an embodiment of a survival lamp unit 11. The survival lamp unit 11 generates lights such that during night rescue the person wearing the life vest 10 can be easily spotted.

The survival lamp unit 11 is automatically triggered without any human intervention. In this fashion the survival lamp unit 11 will operate even when the person wearing the vest is unconscious.

The survival lamp unit 11 is water-actuated. A water-responsive actuator triggers the light source of the survival lamp unit 11 when water splashes the survival lamp unit 11. Once triggered, the light source of the survival lamp unit 11 remains in operation for a period of time largely exceeding the duration of the initial water splash. Periodic water splashing allows re-triggering the light source such that it will remain in operation without the necessity of the water-responsive actuator being continuously immersed in water.

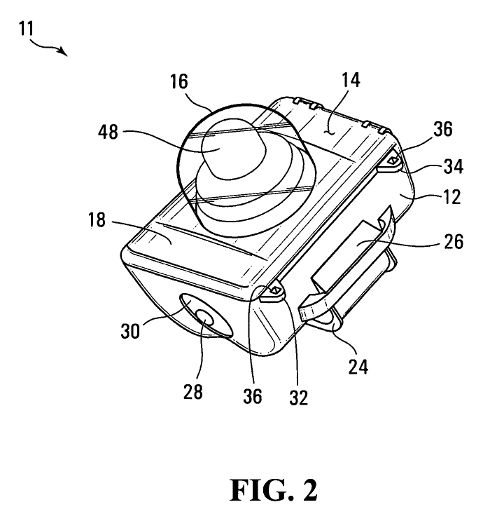

FIG. 2 is a perspective view of the survival lamp unit 11. The survival lamp unit 11 has a plastic housing providing a generally flat upper surface 14 from which projects a light transmissive dome 16 forming a unitary lens structure. The configuration of the dome 16 is such that light produced by the light source within the dome will propagate in substantially all directions of an imaginary upper hemisphere whose base rests on the surface 14. The dome 16 can be made of any suitable light transmissive material that is sturdy enough to withstand the conditions expected during use, without breaking. Polycarbonate is an example of such a material that is virtually transparent and reduces to a minimum the loss of light intensity as light is projected through it.

The dome 16 is surrounded by a reflector 18 designed to reflect upwardly any light that may be directed to it. In this fashion, light that may be output by the light source of the survival lamp unit 11 will be re-directed upwardly. Also light originating from a search light of a rescue vessel will be reflected by the reflector 18. Therefore the reflector 18, in conjunction with the light source mounted within the dome 16 increases the likelihood of spotting the person wearing the life vest 10.

The reflector 18 includes a layer of reflective material. The layer can be formed as a discrete sheet of reflective material that is affixed to the upper surface 14 or it can be a layer of reflective paint material deposited on the upper surface 14.

The lower part of the housing 12 includes a mounting structure to affix the survival lamp unit 11 to the tab 22 of the life vest 10. Many different mounting structures can be provided without departing from the scope of the disclosed technology. In the specific example shown in the drawings, the mounting structure includes a strap 24 which passes below the housing 12.

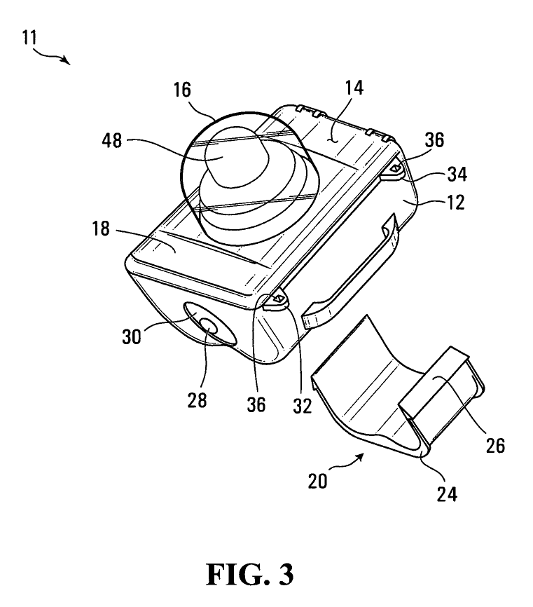

FIG. 3 is another view of the survival lamp unit 11, illustrating in greater detail the mounting structure 20. The strap 24 is shown here including a locking tongue 26 which is inserted into a receptacle defined by a laterally projecting band 28. The tongue engages the projecting band 28 and locks in place. In use, the mounting tab 22 or any other part of the life vest 10 to which the survival lamp unit 11 is to be affixed is passed between the strap 24 and the housing 12, and the strap 24 is locked in place. In this fashion, the survival lamp unit 11 is securely mounted to the life vest.

Referring back to FIG. 2, on one side of the housing 12 is located a manually operable switch 28, in the form of a push-button that is used for periodic testing purposes. As it will be described later, switch 28 can be used to manually trigger the light source of the survival lamp unit 11 for an operative cycle to confirm it operates correctly. The survival lamp unit 11 is a time limited component and usually must be replaced after a time limit whether or not it has been used in the water. Such time limit is usually of several years during which components may deteriorate. To ensure that the survival lamp unit 11 is still in operational condition, tests on it may be performed periodically, say on an annual basis. The test may include a visual inspection of the unit to ensure that it has no broken or missing part followed by a functional test. The functional test consists of actuating the switch 28 which will simulate a water contact and will trigger the survival lamp unit 11 for operative cycle. In this fashion, the person conducting the test can see if the survival lamp unit 11 works as intended.

In certain embodiments, the switch 28 includes a plunger that can be depressed by a finger and a suitable seal 30 to prevent ingress of water when the survival lamp unit 11 is in use. The seal 30 can be in the shape of an O-ring. In other embodiments, the seal 30 can be in the form of a rubber bonnet that covers entirely the switch 28 and prevents water to ingress the housing. The switch 28 is operated via the bonnet by depressing the bonnet which in turn depresses the switch 28.

The housing 12 also includes a pair of spaced apart projections 32, 34 that shield respective electrodes of the water responsive actuator. The projections 32, 34 are integrally formed with the housing 12 and include small apertures 36, that allow water to reach the respective electrodes located right behind each projection 32, 34. The projections 32, 34 protect physically the electrodes against damage and also prevent ready access to the electrodes when the survival lamp unit 11 is not in use. In many applications, such as on large passenger ships, the life vests 10 with survival lamp units 11 are issued to passengers and remain accessible in their cabins during the entire trip. The projections 32, 34 constitute tamper proof shields preventing individuals from touching the electrodes with fingers which may cause the survival lamp unit 11 to be triggered unnecessarily and drain its battery. Objectively, in applications where such tamper proof feature is desired, the switch 28 could be omitted since it also can be used to trigger the survival lamp unit 11. The projections 32, 34 are sized such as to shield sufficiently the electrodes directly under them in a way to prevent a human finger from touching the electrodes when the survival lamp unit 11 is hand manipulated. In the example shown in the drawings, the projections 32, 34 cover entirely the electrodes but provide a water pathway such that when the survival lamp unit 11 is in water, the water will be able to reach the electrodes to trigger the survival lamp unit 11.

It should be appreciated that the tamper proof feature can be achieved in different fashions from the example discussed above. Generally, the tamper proof feature includes a barrier in proximity to the electrode to prevent the finger from coming into contact with the electrode. This barrier can be a projection as in the case of the example shown in FIG. 2, but can also be achieved by recessing the electrode into the housing sufficiently such that a human finger, even when applied directly over the electrode will not be able to reach it and make contact. Many different tamper proof feature variations are possible without departing from the scope of the disclosed technology.

For embodiments where the survival lamp unit 11 is devoid of a switch 28 to trigger the survival lamp unit 11 for testing purposes, a functional test can still be conducted by inserting a thin metallic wire through the water pathway in each projection 32, 34 such as to short-circuit the electrodes and simulate an immersion in water. Therefore, the water pathway should be made sufficiently large to accommodate the testing wire.

In another possible embodiment, the function of the switch 28 can be changed from a trigger of the survival lamp unit 11 to a re-set function where the operation of the survival lamp unit 11 is stopped. This can be useful to limit battery drain during the testing procedure. Therefore the survival lamp unit 11 does not need to be operated during a full operative cycle, but once triggered to visually confirm that it operates it can be turned off by depressing the switch 28.

In yet another possible embodiment, the switch 28 can be used to trigger the survival lamp unit 11 to visually test it and also then to turn it off.

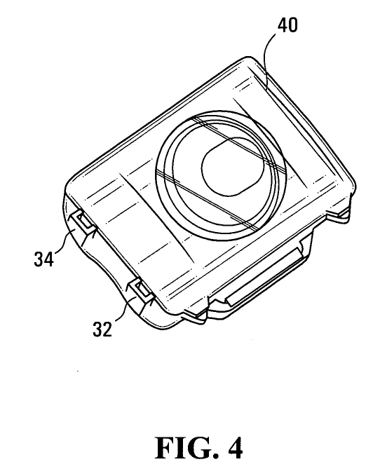

FIG. 4 shows another embodiment of a survival lamp unit 40. The main differences in this embodiment reside in the location of the projections 32, 34 and of the respective electrodes.

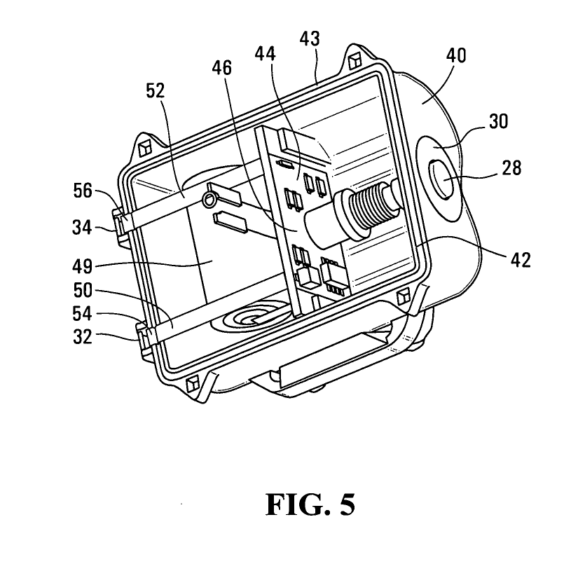

FIG. 5 illustrates the survival lamp unit 40 with the housing opened along an area of juncture 42 which includes a peripheral groove 43 that mates with a corresponding peripheral tongue on the top housing part (not shown). Inside the housing is provided a locating slot 44 that receives and supports a circuit board 46 containing the electronics that operate the survival lamp unit 40. The circuit board also carries the structure of the switch 28 and locates that structure such that it faces the seal 30. Also the circuit board 46 carries the light source 48 which is located within the dome 16 when both parts of the housing are assembled. A power source in the form of a single cell battery 49 is provided below the circuit board 46 and is retained between the circuit board 46 and the housing wall. Above the battery are provided a pair of electrical pathways 50 and 52 that reach to the respective electrodes 54, 56 registering with the projections 32, 34. In this specific example, the electrical pathways 50 and 52 are in the form of thin strips of metallic material, whose upper ends connect to the circuit board 46, and whose lower ends constitute the electrodes 54, 56. The strips of metallic material are flexible and pass over the peripheral groove 43. When the upper part of the housing is mated with the lower part, the tongue (not shown) bends the strips into the groove 43. In this fashion, the housing can be closed in a water-tight manner while maintaining an electrical continuity between the electrodes 54, 56 and without the need to providing dedicated apertures for the electrodes through the housing. The electrodes 54, 56 use the area of juncture as a pathway to penetrate within the housing.

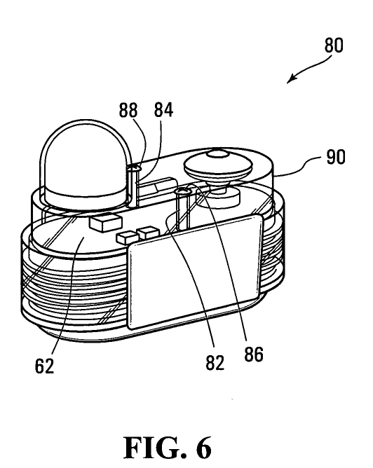

FIG. 6 shows another embodiment of a survival lamp unit 80. Here, electrical pathways 82, 84 leading to the respective electrodes 86, 88 are metal rods that project from the interior of survival lamp unit 80 through apertures in the housing 90 to the electrodes 86, 88. Electrical pathways may be held in place by any suitable method such as by being insert molded into the housing 90. In this exemplary embodiment, O-rings are positioned between the electrical pathways 82, 84 and the housing 90 provide a means of sealing the point of contact between electrical pathways 82, 84 and the housing 90 in a water-tight manner. Electrical pathways 82, 84 are threaded on a portion of their length and hold a printed circuit board comprising microcontroller 62 in place. Advantageously, no sealant or epoxy are needed for the assembly of survival lamp unit 80.

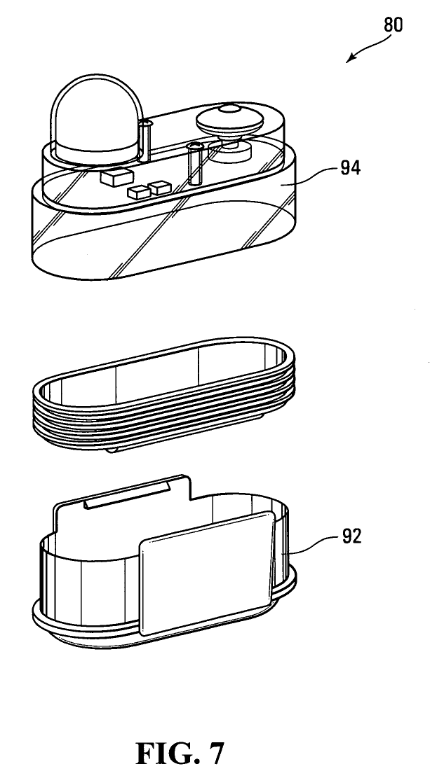

FIG. 7 is a view of the survival lamp unit 80 with the bottom portion 92 of the survival lamp unit 80 disengaged from an upper portion 94 of survival lamp unit 80. The bottom portion 92 contains the battery cell of the survival lamp unit 80 and can be fastened to the upper portion 94 of survival lamp unit 80 in any suitable way. In the example provided here, the bottom is fastened by snap fit to the upper portion 94 survival lamp unit 80.

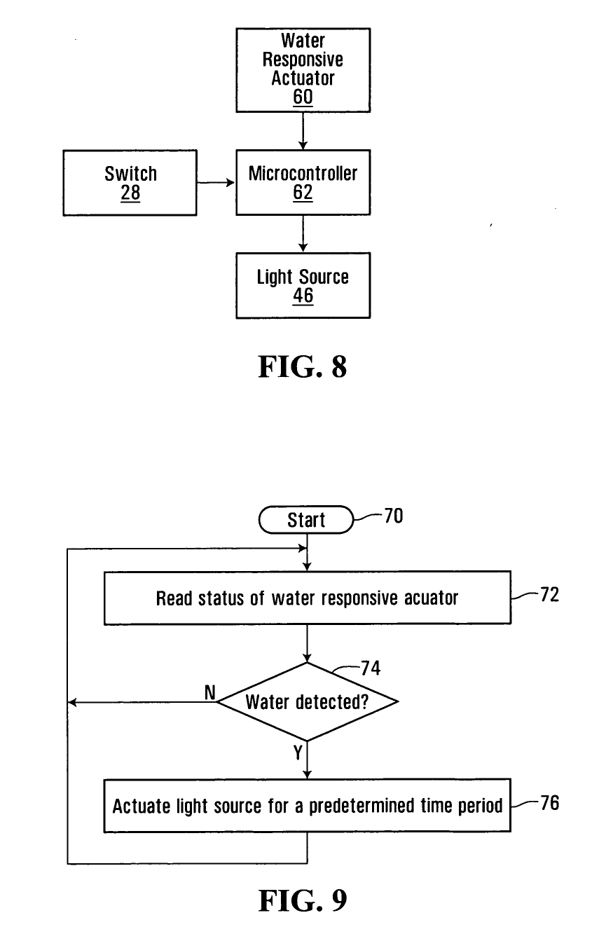

FIG. 8 is a block diagram of the electronics of the survival lamp unit 11, 40. The survival lamp unit 11, 40 includes a water responsive actuator 60 that detects the presence of water. As it will be discussed later, the water responsive actuator senses the impedance between the electrodes 54, 56 in determining if water is present. The output of the water responsive actuator 60 in the form of a signal that conveys the presence or absence of water is delivered to a microcontroller 62. The microcontroller 62 is any suitable component that has the functionality described below. For example, in one embodiment, the microcontroller 62 may be a circuit comprising a 555 timer and a 4017 chip, or a circuit comprising an RC component and a two-stage transistor sub-circuit. In the example provided, the microcontroller 62 is a software operated chip. Microcontroller 62 determines on the basis of the signal provided by the water responsive actuator 60 if the survival lamp unit should be triggered. The status of the switch 28 is also input into the microcontroller 62 such that the microcontroller can activate the survival lamp unit for testing purposes or re-set it, depending upon the specific function of the switch 28.

The output of the microcontroller 62 drives the light source 46. The output determines whether or not the light source is to be actuated or not, the type of actuation (flashing or continuous), in the case of a flashing actuation the flashing frequency and the flash pulse duration.

The flowchart at FIG. 9 describes an exemplary process of how the microcontroller operates the light source 46. The process starts at step 70. At step 72 the microcontroller 62 reads the status of the water responsive actuator 60. At decision step 74, if no water is detected the program returns to step 72 for another loop. However, if water is detected then the microcontroller 62 actuates the light source 46 for a predetermined time period which largely exceeds the time during which the water responsive actuator was in contact with water. Specifically, it suffices for the water responsive actuator to be momentarily immersed into a body of water to trigger the light unit 46 and even if the water responsive actuator is removed from water, the light source 46 will continue to operate for a predetermined time period. The time period may be on the order of 15 seconds, 30 seconds or one or more minutes. If during the time the light unit 46 is active, the microcontroller 62 senses via the water responsive actuator another contact with water, then the time period is reset, and the light unit 46 will be kept active for the entire duration of a full operative cycle (time period).

The water responsive actuator 60 is a circuit that measures the impedance between the electrodes 54, 56 to determine if water is present or not. If the electrodes are immersed in a body of water the impedance between them will be somewhat less than if no water is present. Thus when the survival lamp unit 11 is momentarily dipped into water, the impedance between the electrodes 54, 56 drops and this is detected by the water responsive actuator, which in turn sends a signal to the microcontroller 62 which will trigger the light unit 46 for an operative cycle.

The light unit 46 includes a single LED array. The LED array has a plurality of semi conducting light emitting chips that are encased in a common lens structure through which the semi conducting light emitting chips output light. The LED array may produce white light and the semi conducting light emitting chips may be molded into the light transmissive material of the light transmissive dome 16. The semi conducting light emitting chips output light in different directions such that the single LED array has a hemispheric light emissive pattern. This allows the survival light unit 11 to been seen practically from all directions above the waterline.

In one exemplary implementation, a light unit 46 available from ISP Corp. 209-401 Hyundai-2cha Apt., 924 Dongchun 3-dong Yeonsu-gu, Incheon, 406-725, Korea, under model number 10W4DHCBB-H, has been found satisfactory. The battery that is used in the survival lamp unit 11 should be of sufficient capacity to supply enough energy to power the light unit 46 for a sufficient amount of time. In one exemplary implementation, a battery available form Minamoto Battery Ltd., A6, 8/F., Mei Hing Industrial Building, 16-18 Hing Yip Street, Kwun Tong, Kowloon, Hong-Kong, under model number Model No. ER14250M has been found satisfactory. This battery is a Lithium Thionyl Chloride Battery which is capable of outputting a voltage of 3.6 Volts and has a capacity of 800 mAh. Accordingly, a single battery cell can be used to power the light unit 46 without the need of any voltage boosters. This results in a very simple electric circuit that can be inexpensive to mass produce.

In some implementations (including the implementation introduced in the preceding paragraph), the light unit 46 of the survival lamp unit 11 (and consequently the survival lamp unit 11, 40 itself) is capable of emitting fixed light (continuous mode) in generally all directions of the upper hemisphere with a luminous intensity of least 0.75 cd. When the light unit 46 is operated in a flashing mode, the survival lamp unit 11 is capable of emitting fixed light (continuous mode) in generally all directions of the upper hemisphere with an effective luminous intensity of least 0.75 cd. Techniques to assess the luminous intensity and the light distribution pattern of a fixed light and the effective luminous intensity and the light distribution pattern of a flashing light are well known in the art and need not be described here. When the exemplary implementation is operated in the flashing mode in which the light unit 46 is flashed at a frequency in the range of 50 to 70 flashes per minute, the battery capacity is sufficient to keep the light unit 46 continuously in operation for a period of at least 8 hours. In this implementation, the duration of the flash is in the range of 200 to 350 milliseconds.

When designing the survival lamp unit 11, it is generally desirable to use a battery that has a sufficient operational capacity and also capacity for testing the light unit 46. In other words, the battery capacity should be selected to contain enough energy for a number of test cycles, say one a year over the operational life of the survival lamp unit 11, and the remainder should suffice to keep the survival lamp unit 11, 40 working for the minimal time required when immersed in water.

Although various embodiments have been illustrated, this was for the purpose of describing, but not limiting, the invention. Various modifications will become apparent to those skilled in the art and are within the scope of this invention, which is defined more particularly by the attached claims.

What is claimed is:

1. A water activated survival lamp unit for mounting to a flotation device above and in proximity to the water line, the survival lamp unit comprising:
a light source including a LED array having a plurality of semi conducting light emitting chips encased in a unitary lens structure through which the semi conducting light emitting chips output light;
a battery connected for supplying energy to the light source;
a water responsive actuator for controlling operation of the light source, responsive to a momentary contact with a coherent body of water for actuating the light source for an operative cycle of a time period largely exceeding a duration of the momentary contact,
the survival lamp unit when actuated emitting either fixed light or flashing light in generally all directions of the upper hemisphere with a luminous intensity of least 0.75 cd if the light source emits fixed light, or an effective luminous intensity of at least 0.75 cd if the light source emits flashing light.

2. A water activated survival lamp unit as defined in claim 1, wherein the unitary lens structure includes a body of light transmissive material in which the semi conducting light emitting chips are molded.

3. A water activated survival lamp unit as defined in claim 1, wherein the light source consists of the LED array.

4. A water activated survival lamp unit as defined in claim 3, wherein the LED array when actuated emits either fixed light or flashing light in generally all directions of the upper hemisphere with a luminous intensity of least 0.75 cd if the light source emits fixed light, or an effective luminous intensity of at least 0.75 cd if the light source emits flashing light.

5. A water activated survival lamp unit as defined in claim 4, including a housing having at least a portion thereof that is light transmissive, the LED array being mounted in the housing such that light output by the LED array is emitted from the light transmissive portion in generally all directions of the upper hemisphere.

6. A water actuated survival lamp unit as defined in claim 1, wherein the LED array outputs white light.

7. A water actuated survival lamp unit as defined in claim 1, wherein the LED array outputs flashing light, the flashing light flashing at a frequency of not less than 50 flashes per minute.

8. A water actuated survival lamp unit as defined in claim 7, wherein the LED array outputs flashing light, the flashing light flashing at a frequency of not more than 70 flashes per minute.

9. A water actuated survival lamp unit as defined in claim 3, wherein the battery is a single cell battery.

10. A water actuated survival lamp unit as defined in claim 9 wherein the single cell battery has a capacity sufficient to power the LED array to emit flashing light continuously for a period of at least 8 hours.

11. A water actuated survival lamp unit as defined in claim 1 wherein the battery outputs a sufficient voltage to operate the LED array without a voltage booster in the electrical path between the battery and the LED array.

12. A water actuated survival lamp unit as defied in claim 11, wherein the battery is a lithium thionyl chloride battery.

13. A water actuated survival lamp unit as defined in claim 11, wherein the battery outputs a voltage of 3.6 volts or more.

14. A water actuated survival lamp unit as defined in claim 1, wherein the LED array emits flashing light, the water actuated survival lamp unit including a microcontroller to regulate a flashing frequency of the LED array.

15. A water actuated survival lamp unit as defined in claim 5, wherein the portion of the housing that is light transmissive is dome shaped.

16. A water actuated survival lamp unit as defined in claim 1, including a manually operable switch to test the water actuated survival lamp unit.

17. A water actuated survival lamp unit as defined in claim 16, wherein the switch includes a push-button.

18. A water actuated survival lamp unit as defined in claim 16, wherein the manually operable switch, when actuated causes actuation of the LED array for a predetermined time period.

19. A water actuated survival lamp unit as defined in claim 2, wherein the housing has two sections that mate with one another along an area of juncture.

20. A water actuated survival lamp unit as defined in claim 19, wherein the water responsive actuator includes at least one electrode exposed outside the housing, and an electrical pathway from the electrode to the interior of the housing, the electrical pathway passing between the sections through the area of juncture.

21. A water actuated survival lamp unit as defined in claim 1 wherein the water responsive actuator includes at least one electrode exposed outside the housing, and an electrical pathway from the at least one electrode to the interior of the housing, the electrical pathway passing through an aperture in the housing.

22. A water actuated survival lamp unit as defined in claim 21, wherein the electrical pathway is insert molded into the housing.

23. A water actuated survival lamp unit as defined in claim 21, comprising an O-ring between the electrical pathway and the housing for creating a water-tight seal.

24. A water actuated survival lamp unit as defined in claim 20, wherein the water responsive actuator includes a pair of electrodes exposed outside the housing, an electrical pathway from each electrode to the interior of the housing, the electrical pathway passing between the sections through the area of juncture.

25. A life vest including the survival lamp unit defined in claim 1.

26. A method for determining a capacity of a battery of a water activated survival lamp, the water activated survival lamp unit intended for mounting to a flotation device above and in proximity to the water line, the survival lamp unit comprising a light source including a battery operated LED array having a plurality of semi conducting light emitting chips encased in a unitary lens structure through which the semi conducting light emitting chips output light, and water responsive actuator for controlling operation of the light source, responsive to a momentary contact with a coherent body of water for actuating the light source for an operative cycle of a time period largely exceeding a duration of the momentary contact, the method comprising:
determining a first energy requirement for the survival lamp unit such that when actuated it emits either fixed light or flashing light in generally all directions of the upper hemisphere with a luminous intensity of least 0.75 cd of at least 8 hours of continuous operation if the light source emits fixed light, or an effective luminous intensity of at least 0.75 cd of at least 8 hours of continuous operation if the light source emits flashing light;
determining a second energy requirement to perform a test cycle of the survival lamp unit at least 5 times, wherein a test cycle includes actuating the survival lamp unit over a certain period of time; and
selecting a battery that has a capacity sufficient to meet the first energy requirement and the second energy requirement.

27. A water activated survival lamp unit for mounting to a flotation device above and in proximity to the water line, the survival lamp unit comprising:
a housing including at least two sections mated to one another along an area of juncture;
a light source including a LED light unit mounted in the housing;
a battery connected for supplying energy to the light source, mounted in the housing; and
a water responsive actuator for controlling operation of the light source, responsive to a momentary contact with a coherent body of water for actuating the light source for an operative cycle of a time period largely exceeding a duration of the momentary contact,
the water responsive actuator including:
at least one electrode projecting outside the housing; and
an electrical pathway from the electrode to the interior of the housing,
the electrical pathway passing between the mated sections through the area of juncture.

28. A water activated survival lamp unit as defined in claim 27, wherein the water responsive actuator has a pair of electrodes exposed outside the housing, an electrical pathway from each electrode to the interior of the housing, the electrical pathway passing between the sections through the area of juncture.

29. A water activated survival lamp unit for mounting to a flotation device above and in proximity to the water line, the survival lamp unit comprising:
a housing;
a light source including a LED light unit mounted in the housing;
a battery connected for supplying energy to the light source, mounted in the housing;
a water responsive actuator for controlling operation of the light source, responsive to a momentary contact with a coherent body of water for actuating the light source for an operative cycle of a time period largely exceeding a duration of the momentary contact, the water responsive actuator including at least one electrode projecting outside the housing; and
a tamper-proof structure associated with the electrode to prevent contact between the electrode and the skin when the survival lamp unit is hand-manipulated.

30. A survival lamp unit as defined in claim 29 wherein the tamper proof structure includes one or more passageways to allow water outside the housing to reach the electrode.

31. A survival lamp unit as defined in claim 29, wherein the tamper proof structure includes a projection overlying the electrode.

32. A survival lamp unit as defined in claim 29, wherein the tamper proof structure includes a portion of the housing in which the electrode is sufficiently recessed such that the portion prevents the skin to contact the electrode when the survival lamp unit is manipulated with a hand.
